(19) United States
(12) Patent Application Publication
(10) Pub. No.: US 2026/0066903 A1
(43) Pub. Date: Mar. 5, 2026

(54) LEVEL SHIFTER

(71) Applicant: TEXAS INSTRUMENTS INCORPORATED, Dallas, TX (US)

(72) Inventor: Alex WU, Federal Way, WA (US)

(21) Appl. No.: 18/818,322

(22) Filed: Aug. 28, 2024

(51) Int. Cl. H03K 19/0185; H03K 3/356

(52) U.S. Cl. CPC H03K 19/018521; H03K 3/356113

(57) ABSTRACT

In some examples, an apparatus includes a first level shifter circuit having first, second, third, and fourth inputs. The apparatus also includes a second level shifter circuit having first and second inputs, and first and second outputs. The first input of the second level shifter circuit is coupled to the first input of the first level shifter circuit. The second input of the second level shifter circuit is coupled to the second input of the first level shifter circuit. The first output of the second level shifter circuit is coupled to the third input of the first level shifter circuit. The second output of the second level shifter circuit coupled to the fourth input of the first level shifter circuit.

### BACKGROUND

A level shifter is a circuit, component, or device that translates a received input signal from a first voltage domain or logic level to a second voltage domain or logic level for providing as an output signal. The output signal may be greater in value than the input signal or lesser in value than the input signal. A level shifter may be uni-directional or bi-directional and may facilitate compatibility between components or devices that may otherwise not be compatible based on their respective voltage specifications (e.g., such as the respective voltage domains in which the components operate).

### SUMMARY

In some examples, an apparatus includes a first transistor, a voltage source, a second transistor, a third transistor, a first capacitor, and a level shifter. The first transistor has a control terminal and first and second terminals, the first terminal of the first transistor coupled to a first voltage terminal. The voltage source has first and second terminals, the first terminal of the voltage source coupled to the first voltage terminal. The second transistor has a control terminal and first and second terminals, the first terminal of the second transistor coupled to the second terminal of the first transistor, and the control terminal of the second transistor coupled to the second terminal of the voltage source. The third transistor has a control terminal and first and second terminals, the first terminal of the third transistor coupled to the second terminal of the second transistor. The first capacitor has first and second terminals, the first terminal of the first capacitor coupled to the control terminal of the first transistor, the second terminal of the first capacitor coupled to the control terminal of the third transistor. The level shifter circuit has first and second inputs, and a first output, the first input of the level shifter circuit coupled to the second terminal of the third transistor, the second input of the level shifter circuit coupled to the control terminal of the third transistor, and the first output of the level shifter circuit coupled to the control terminal of the first transistor.

In some examples, an apparatus includes a first level shifter circuit having first, second, third, and fourth inputs, and a second level shifter circuit having first and second inputs, and first and second outputs. The first input of the second level shifter circuit coupled to the first input of the first level shifter circuit, the second input of the second level shifter circuit coupled to the second input of the first level shifter circuit, the first output of the second level shifter circuit coupled to the third input of the first level shifter circuit, and the second output of the second level shifter circuit coupled to the fourth input of the first level shifter circuit.

In some examples, a system includes a first circuit, a second circuit, a level shifter circuit, and a driver circuit. The first circuit has first and second outputs, the first circuit configured to operate in a first voltage domain. The second circuit has an input, the second circuit configured to operate in a second voltage domain. The level shifter circuit has first, second, third, and fourth inputs, and an output, the first input of the level shifter circuit coupled to the first output of the first circuit, the second input of the level shifter circuit coupled to the second output of the first circuit, and the output of the level shifter circuit coupled to the input of the second circuit, wherein the level shifter is configured to convert a signal received from the first circuit from the first voltage domain to the second voltage domain. The driver circuit has first and second inputs, and first and second outputs. The first input of the driver circuit is coupled to the first input of the level shifter circuit. The second input of the driver circuit is coupled to the second input of the level shifter circuit. The first output of the driver circuit is coupled to the third input of the level shifter circuit. The second output of the driver circuit is coupled to the fourth input of the level shifter circuit. The driver circuit is configured to drive the level shifter circuit in converting the signal from the first voltage domain to the second voltage domain.

### BRIEF DESCRIPTION OF THE DRAWINGS

FIG. 1 is a block diagram of an example system for implementing level shifting.

FIG. 2 is a schematic diagram of an example level shifter circuit.

FIG. 3 is a schematic diagram of an example driver circuit.

FIG. 4 is a timing diagram of example signals in a system implementing level shifting.

FIG. 5 is a flow diagram of an example method for implementing level shifting.

### DETAILED DESCRIPTION

As described above, a level shifter may facilitate voltage compatibility between components that may otherwise operate in voltage domains or voltage ranges that are incompatible with one another. In some cases, the voltage domains are low voltage and high voltage domains, respectively. For example, the low voltage domain may have an upper limit of less than or equal to about 1.1 volts (V) and the high voltage domain may have a lower limit greater than or equal to about 1.8 V. In some examples, the low voltage domain may have an upper limit of less than or equal to about 0.9 V. In various other cases, other suitable voltage ranges are possible for the low voltage domain and/or the high voltage domain.

Various challenges may exist in level shifter architecture design. For example, at least some nets or nodes of the level shifter may not be initialized at startup of the level shifter and until a first edge of an input signal of the level shifter has arrived. This may cause the nets or nodes to initialize in the wrong state, resulting in a glitch in an output signal of the level shifter and/or one or more components of the level shifter being subjected to overvoltage conditions. These overvoltage conditions may damage, or even destroy, at least some of the components.

A level shifter according to this description at least partially mitigates the effects of and/or compensates for these challenges. In some examples, a driver drives a level shifter (which may also be referred to as a level shifter circuit). The driver may drive the level shifter based on input signals received by the level shifter. For example, the level shifter may be a high-speed level shifter with an alternating current (AC) coupling capacitor. The driver, in some examples, may be a direct current (DC) level shifter. The driver and level shifter may receive and operate according to a same input signal. In some examples, based on the input signal, the driver drives the level shifter to set an initial state of the level shifter. Subsequently, the level shifter may convert the input signal from a first voltage domain to an output signal in a second voltage domain. By driving the level shifter to set the initial state of the level shifter, the driver reduces a likelihood of the level shifter initializing in the wrong state, as described above, thereby mitigating the occurrence of a resulting glitch in the output signal of the level shifter.

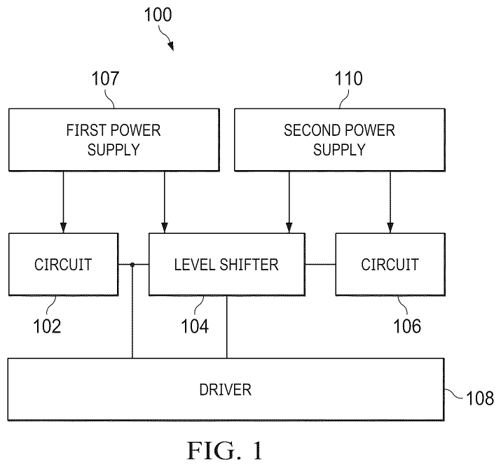

FIG. 1 is a block diagram of an example system 100 for implementing level shifting. In at least some examples, the system 100 is representative of, or implemented in, an automobile or other vehicular environment in which certain components may operate in, or according to, a first voltage domain and other components may operate in, or according to, a second voltage domain, such as a laptop computer, a smartphone, a wearable device, a tablet device, or the like. In an example, the system 100 includes a circuit 102, a level shifter 104, a circuit 106, and a driver 108. The system 100 may also include, or be coupled to, a first power supply 107 and a second power supply 110. In at least some examples, the circuit 102 receives power from the first power supply 107 and operates in the first voltage domain. Similarly, the circuit 106 receives power from the second power supply 110 and operates in the second voltage domain. Generally, the circuit 102 and the circuit 106 may not be interoperable with one another resulting from their operation in different voltage domains. For example, a digital output signal provided by the circuit 102 having a first value may be interpreted by the circuit 106 as having a value other than the first value resulting from the circuit 102 and the circuit 106 operating in different voltage domains.

To provide interoperability between the circuit 102 and the circuit 106, in at least some examples, the level shifter 104 is coupled between the circuit 102 and the circuit 106. The level shifter 104 is also coupled to both the first power supply 107 and the second power supply 110. As such, the level shifter 104 may translate between the first voltage domain and the second voltage domain. For example, in some implementations the level shifter 104 receives an input signal from the circuit 102 having a value specified according to the second voltage domain and provides an output signal to the circuit 106 having a value specified according to the first voltage domain. In this way, if the value specified according to the second voltage domain is representative of a first digital value, the value specified according to the first voltage domain is also representative of the first digital value. Similarly, if the value specified according to the second voltage domain is representative of a second digital value, the value specified according to the first voltage domain is also representative of the second digital value. As described above, in some examples, the driver 108 drives the level shifter 104. For example, responsive to startup of the system 100, the driver 108 drives the level shifter 104 to set an initial state of the level shifter 104, and correspondingly an initial value of an output signal of the level shifter 104. In some examples, the driver 108 is also a level shifter, such as a DC level shifter.

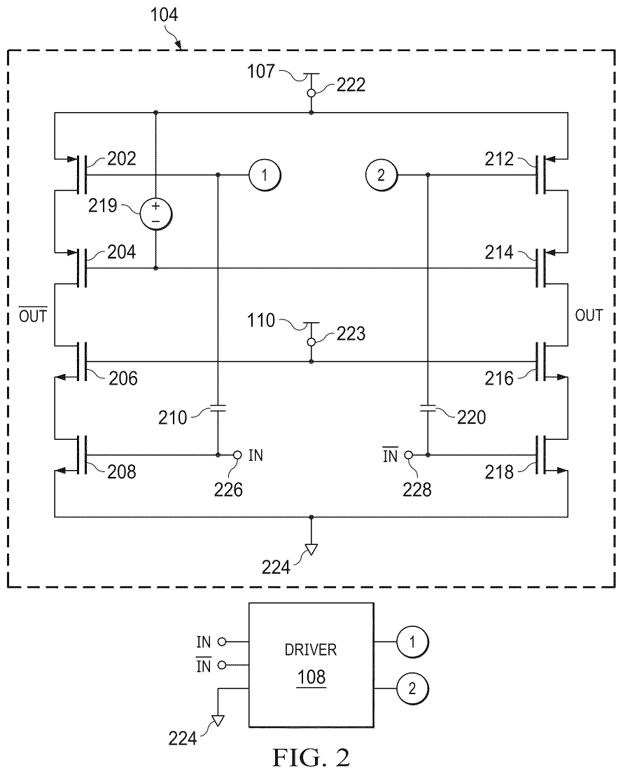

FIG. 2 is a schematic diagram of an example of the level shifter 104 with a block diagram representation of an example of the driver 108. In an example, the level shifter 104 includes a transistor 202, a transistor 204, a transistor 206, a transistor 208, a capacitor 210, a transistor 212, a transistor 214, a transistor 216, a transistor 218, a capacitor 220, and a voltage source 221.

In an example architecture of the level shifter 104, the transistor 202 has a drain, has a source coupled to a voltage terminal 222 and has a gate coupled to a first output of the driver 108. The transistor 204 has a source coupled to the drain of the transistor 202. The transistor 204 also has a drain and a gate. The transistor 206 has a drain coupled to the drain of the transistor 204 and a gate coupled to a terminal 223. The transistor 206 also has a source. The transistor 208 has a drain coupled to the source of the transistor 206, a source coupled to a ground terminal 224, and a gate coupled to a terminal 226. The capacitor 210 has a first terminal coupled to the gate of the transistor 202 and has a second terminal coupled to the gate of the transistor 208. As used herein, the drain and the source of a transistor may be referred to as either a first terminal or a second terminal of the transistor. Similarly, a gate of a transistor may be referred to as a control terminal of the transistor.

Continuing the example, the transistor 212 has a drain, has a source coupled to the voltage terminal 222 and has a gate coupled to a second output of the driver 108. The transistor 214 has a source coupled to the drain of the transistor 212. The transistor 214 also has a drain and a gate. The transistor 216 has a drain coupled to the drain of the transistor 214 and a gate coupled to the terminal 223. The transistor 216 also has a source. The transistor 218 has a drain coupled to the source of the transistor 216, a source coupled to the ground terminal 224, and a gate coupled to a terminal 228. The capacitor 220 has a first terminal coupled to the gate of the transistor 212 and has a second terminal coupled to the gate of the transistor 218. The voltage source 219 has a first terminal coupled to the voltage terminal 222 and has a second terminal coupled to the fate terminal of the transistor 204. In some examples, the transistors 206 and 216 may be omitted.

In an example, the voltage terminal 222 is coupled to the first power supply 107, and the terminal 223 is coupled to the second power supply 110. In an example, an input signal (IN) is received at the terminal 226, and an inverse of the input signal (¿̅) is received at the terminal 228. An output signal (OUT) of the level shifter 104 is provided at the drain of the transistor 216, and an inverse of the output signal (O̅U̅T̅) is provided at the drain of the transistor 206. In an example, the voltage source 219 has a positive terminal coupled to the voltage terminal 222 and a negative terminal coupled to the gate of the transistor 204. In some examples, an inverter (not shown) is coupled between the terminal 226 and the terminal 228 such that the level shifter 104 receives IN from the circuit 102 and the inverter provides ¿̅ having an inverse value of IN.

In an example of operation of the level shifter 104, responsive to IN having a low value (e.g., a value of about 0 V), the gate of the transistor 202 is driven by IN through the capacitor 210, such as via capacitive coupling, and the gate of the transistor 212 is driven by ¿̅ through the capacitor 220, also such as via capacitive coupling. The capacitor 210 charges to approximately a value of the signal provided by the driver 108 at the gate of the transistor 202. In some examples, the value of the signal provided by the driver 108 at the gate of the transistor 202 is a low value, such as value of about 0 V in the example of FIG. 2, sufficient to cause the transistor 202 to turn on, becoming conductive in a forward direction. The transistors 204, 214 are biased by the voltage source 219 to cause the transistors 204, 214 to remain in a conductive state in the forward direction. In some examples, the transistors 204, 214 are cascode transistors to protect the transistors 202, 212, respectively, from experiencing excess drain voltage, which may damage the respective transistor 202, 212. Similarly, the transistors 206, 216 are cascode transistors to protect the transistors 208, 218, respectively, from experiencing excess drain voltage, which may damage the respective transistor 208, 218. In some examples, at least some of the transistors 204, 214, 206, 216 may be omitted from the level shifter 104, such as in examples in which the transistors 202, 212, 208, 218 can tolerate a voltage at least equal to a value of the voltage provided by voltage provided by the second power supply 110. The transistor 208 remains in a non-conductive state in the forward direction resulting from IN having the low value. As a result, the transistors 202, 204, 206 pull up a value of O̅U̅T̅ to approximately equal a value of the signal provided at the voltage terminal 222. Similarly, the transistor 218 turns on, pulling down a value of OUT to approximately equal a value of a ground potential provided at the ground terminal 224. The transistor 212 may remain turned off resulting from the driver 108 driving the gate of the transistor 212 to have a high value, such a value of about 1.1 V in the example of FIG. 2, sufficient to cause the transistor 212 to be substantially nonconductive in a forward direction.

Responsive to IN changing to have a high value (e.g., a value of about 1.1 V in the example of FIG. 2), the gate of the transistor 202 is again driven by IN through the capacitor 210, such as via capacitive coupling, and the gate of the transistor 212 is again driven by ¿̅ through the capacitor 220, also such as via capacitive coupling. The capacitor 210 charges to approximately a value of the signal provided by the driver 108 at the gate of the transistor 202. In some examples, the value of the signal provided by the driver 108 at the gate of the transistor 202 is a high value, such as value of about 1.8 V (or any other suitable value) in the example of FIG. 2, sufficient to cause the transistor 202 to turn off, becoming substantially nonconductive in the forward direction. The transistors 204, 214 remain biased by the voltage source 219 to cause the transistors 204, 214 to remain in the conductive state in the forward direction. The transistor 208 is placed in a conductive state in the forward direction resulting from IN having the high value. As a result, the transistors 208 and 206 pull down a value of O̅U̅T̅ to approximately equal the value of the ground potential provided at the ground terminal 224.

Similarly, the value of the signal provided by the driver 108 at the gate of the transistor 212 is a low value, such as value of about 0.9 V (or any other suitable value) in the example of FIG. 2, sufficient to cause the transistor 212 to turn on, becoming conductive in the forward direction. The transistor 218 remains in a non-conductive state in the forward direction resulting from ¿̅ having the low value, such a value of about 0 V in the example of FIG. 2, sufficient to cause the transistor 218 to be substantially nonconductive in the forward direction. As a result, the transistors 212, 214 pull up a value of OUT to approximately equal a value of the signal provided at the voltage terminal 222.

In some examples, the voltage source 219 provides a voltage such that, coupled as shown in FIG. 2, a value approximately equal to a voltage provided by the first power supply 107 minus a voltage provided by the voltage source 219 is provided at the negative terminal of the voltage source 219 to bias the transistors 204, 214, as described above. The voltage source 219 may provide a voltage having any suitable value. In some examples, a value of the voltage provided by the voltage source 219 may be about 0.9 V. Generally, the value of the voltage provided by the voltage source 219 may be approximately equal to a value of a voltage provided by the second power supply 110 (e.g., a voltage of OUT when OUT has a high value) minus a voltage limit of the various semiconductor devices of the level shifter 104. For example, each semiconductor device of the level shifter 104 may have a maximum tolerable voltage after which the respective device may become damaged. The voltage limit of the various semiconductor devices of the level shifter 104 may be a lowest value from among the maximum tolerable voltages of the semiconductor devices (or other components) of the level shifter 104. The voltage source 219 may have any suitable architecture, the scope of which is not limited herein. In at least some examples, the voltage source 219 may be implemented as a voltage divider (not shown) coupled between the voltage terminal 222 and the ground terminal 224.

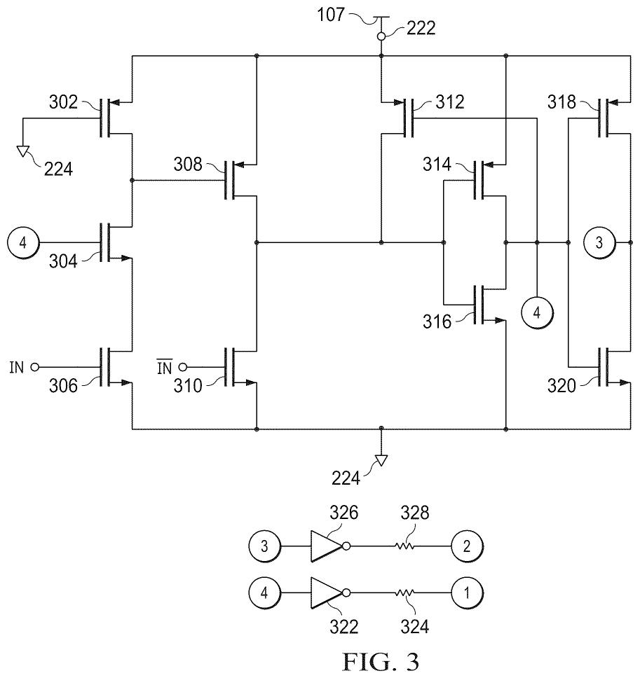

FIG. 3 is a schematic diagram of an example of the driver 108. In an example, the driver 108 includes transistors 302, 304, 306, 308, 310, 312, 314, 316, 318, and 320, an inverter circuit 322, a resistor 324, an inverter circuit 326, and a resistor 328. In some examples, the driver 108 comprises or functions as a level shifter circuit.

In an example architecture of the driver 108, the transistor 302 has a source coupled to the voltage terminal 222, a gate coupled to the ground terminal 224, and has a drain. The transistor 304 has a drain coupled to the drain of the transistor 302 and has a source and a gate. The transistor 306 has a drain coupled to the source of the transistor 304, a source coupled to the ground terminal 224, and a gate terminal at which IN is provided. For example, the gate terminal of the transistor 306 may be coupled to the terminal 226, described above with respect to FIG. 2. The transistor 308 has a source coupled to the voltage terminal 222, a gate coupled to the drain of the transistor 302 and has a drain. The transistor 310 has a drain coupled to the drain of the transistor 308, a source coupled to the ground terminal 224, and a gate terminal at which ¿̅ is provided. For example, the gate terminal of the transistor 308 may be coupled to the terminal 228, described above with respect to FIG. 2. The transistor 312 has a source coupled to the voltage terminal 222, a drain coupled to the drain of the transistor 308, and a gate coupled to the gate of the transistor 304. The transistor 314 has a source coupled to the voltage terminal 222, a drain coupled to the gate of the transistor 312, and a gate coupled to the drain of the transistor 308. The transistor 316 has a drain coupled to the drain of the transistor 314, a source coupled to the ground terminal 224, and a gate coupled to the drain of the transistor 308. In an example, the transistors 314, 316 implement an inverter having an input at their respective gates and an output at their respective drains. The transistor 318 has a source coupled to the voltage terminal 222, a gate coupled feedback to the drain of the transistor 314, and has a drain. The transistor 320 has a drain coupled to the drain of the transistor 318, a source coupled to the ground terminal 224, and a gate coupled to the drain of the transistor 314. In an example, the transistors 318, 320 implement an inverter having an input at their respective gates and an output at their respective drains. The inverter circuit 322 has an input coupled to the drain of the transistor 314 and has an output. The resistor 324 has a first terminal coupled to the output of the inverter circuit 322 and has a second terminal coupled to a first output of the driver 108. In some examples, the second terminal of the resistor 324 is coupled to the gate of the transistor 202. The inverter circuit 326 has an input coupled to the drain of the transistor 318 and has an output. The resistor 328 has a first terminal coupled to the output of the inverter circuit 326 and has a second terminal coupled to a second output of the driver 108. In some examples, the second terminal of the resistor 328 is coupled to the gate of the transistor 212. Although not shown in FIG. 3, in some examples, the inverter circuits 322, 326 have voltage supply terminals coupled to the voltage terminal 222 and have ground terminals coupled to the second terminal of the voltage source 219.

In an example of operation of the driver 108 of FIG. 3, the transistor 302 is held in a conductive state in the forward direction via the arrangement of couplings at its source and gate. Responsive to IN having a low value, and correspondingly ¿̅ having a high value, the transistors 304, 310, 314, and 320 are turned on, becoming conductive in a forward direction. Conversely, the transistors 306, 308, 312, 316, 318 are turned off, being non-conductive in a forward direction. In this arrangement, the transistor 314 provides approximately a voltage of the power supply 107 at the drain of the transistor 314. In turn, the transistor 320 being on provides approximately a ground voltage potential provided at the ground terminal 224 at the drain of the transistor 320.

Responsive to receipt of a rising edge in IN (e.g., IN transitioning from a low value to a high value), The transistors 304, 310, 314, and 320 are turned off and the transistors 306, 316, 318 are turned on. Momentarily, both the transistor 304 and the transistor 306 are turned on responsive to receipt of the rising edge in IN. In some examples, the transistor 302 is a comparatively weak device (e.g., having a conductivity less than that of the transistors 304, 306). As a result, the overlap causes the gate of the transistor 308 to be momentarily pulled down to approximately a ground voltage potential provided at the ground terminal 224, causing the transistor 308 to turn on. The transistor 308 turning on pulls up the gates of the transistors 314, 316, providing approximately the ground voltage potential at the drain of the transistor 316. In turn, the transistor 318 being on provides approximately a voltage of the power supply 107 at the drain of the transistor 318. In addition, the transistor 312 turns on to pull up the gates of the transistors 314, 316. Following the momentary overlap of both the transistor 304 and the transistor 306 being turned on, the transistor 304 turns off, thereby causing the transistor 308 to be turned off.

The inverter circuit 322 inverts a value of a signal provided at the drains of the transistors 314, 316 to provide a first output signal of the driver 108. Similarly, the inverter circuit 326 inverts a value of a signal provided at the drains of the transistors 318, 320 to provide a second output signal of the driver 108. In the example of the system 100, the driver 108 provides the first output signal at the gate of the transistor 202 and provides the second output signal at the gate of the transistor 212, each of the level shifter 104. Thus, the driver 108 drives the transistors 202, 212 via the first and second output signals, respectively, of the driver 108.

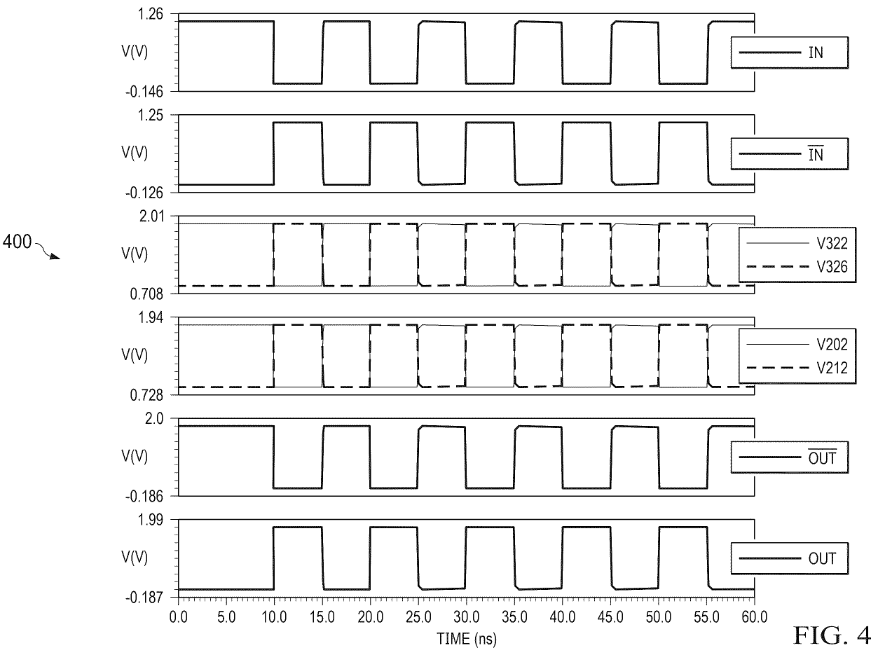

FIG. 4 is a timing diagram 400 of example signals in a system implementing level shifting. In an example, the diagram 400 is representative of at least some signals that may be present in the system 100 of FIG. 1, such as the level shifter 104 and the driver 108. The diagram 400 includes IN, ¿̅, a voltage provided at the output of the inverter circuit 322 (V322), a voltage provided at the output of the inverter circuit 326 (V326), a voltage provided at the gate of the transistor 202 (V202), a voltage provided at the gate of the transistor 212 (V212)), OUT, and O̅U̅T̅. Each signal of the diagram 900 is shown having a vertical axis representative of voltage in units of V and a horizontal axis representative of time in units of nanoseconds (ns).

As shown in the diagram 400, responsive to IN having a high value, the level shifter 104 provides OUT having a high value with a magnitude greater than IN and both ¿̅ and O̅U̅T̅ having low values. Similarly, the driver 108 generates V326 having a voltage approximately equal to O̅U̅T̅ and V322 having a voltage approximately equal to OUT. V326 may be attenuated by the resistor 328 and provided as V212 to drive the transistor 212. Similarly, V322 may be attenuated by the resistor 324 and provided as V202 to drive the transistor 202.

As also shown in the diagram 400, responsive to IN having a low value, the level shifter 104 provides OUT having a low value and provides both ¿̅ and OUT having high values with O̅U̅T̅ having a magnitude greater than ¿̅. Similarly, the driver 108 generates V326 having a voltage approximately equal to O̅U̅T̅ and V322 having a voltage approximately equal to OUT. V326 may be attenuated by the resistor 328 and provided as V212 to drive the transistor 212. Similarly, V322 may be attenuated by the resistor 324 and provided as V202 to drive the transistor 202.

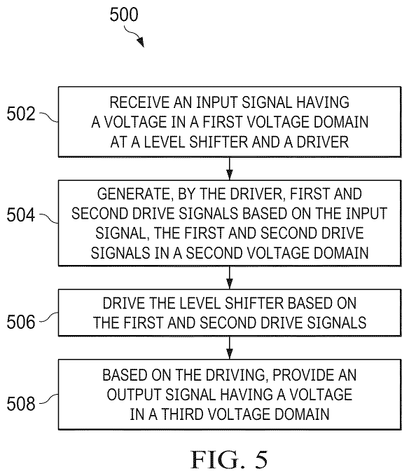

FIG. 5 is a flow diagram of an example method 600 for implementing level shifting. The method 500 may be implemented, at least in part, by the system 100. For example, the method 500 may be implemented at least in part by the level shifter 104 and/or the driver 108.

At operation 502, a level shifter and a driver both receive an input signal having a voltage in a first voltage domain. At operation 504, the driver generates first and second drive signals based on the input signal. In an example, the first and second drive signals are in a second voltage domain that is different from the first voltage domain. In some examples, the second voltage domain includes voltages greater than the first voltage domain. In other examples, the second voltage domain includes voltages lesser than the first voltage domain. At operation 506, the driver drives the level shifter based on the first and second drive signals. In some examples, the driver drives the level shifter to set an initial state of the level shifter based on a value of the input signal. By driving the level shifter to set the initial state of the level shifter, a probability of the level shifter initializing in the wrong state and thereby resulting in a glitch in an output signal of the level shifter and/or one or more components of the level shifter being subjected to overvoltage conditions may be mitigated. At operation 508, based on the driving of the driver and receipt of the input signal, the level shifter provides an output signal having a voltage in a third voltage domain. In some examples, the third voltage domain includes voltages greater than the first voltage domain. In other examples, the third voltage domain includes voltages lesser than the first voltage domain. In some examples, the third voltage domain and the second voltage domain may be the same.

In this description, the term “couple” may cover connections, communications, or signal paths that enable a functional relationship consistent with this description. For example, if device A provides a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. An apparatus, comprising:
a first transistor having a control terminal and first and second terminals, the first terminal of the first transistor coupled to a first voltage terminal;
a voltage source having first and second terminals, the first terminal of the voltage source coupled to the first voltage terminal
a second transistor having a control terminal and first and second terminals, the first terminal of the second transistor coupled to the second terminal of the first transistor, and the control terminal of the second transistor coupled to the second terminal of the voltage source;
a third transistor having a control terminal and first and second terminals, the first terminal of the third transistor coupled to the second terminal of the second transistor;
a first capacitor having first and second terminals, the first terminal of the first capacitor coupled to the control terminal of the first transistor, the second terminal of the first capacitor coupled to the control terminal of the third transistor; and
a level shifter circuit having first and second inputs, and a first output, the first input of the level shifter circuit coupled to the second terminal of the third transistor, the second input of the level shifter circuit coupled to the control terminal of the third transistor, and the first output of the level shifter circuit coupled to the control terminal of the first transistor.

2. The apparatus of claim 1, further comprising:
a fourth transistor having a control terminal and first and second terminals, the first terminal of the fourth transistor coupled to the first voltage terminal;
a fifth transistor having a control terminal and first and second terminals, the first terminal of the fifth transistor coupled to the second terminal of the fourth transistor, and the control terminal of the fifth transistor coupled to the second terminal of the voltage source;
a sixth transistor having a control terminal and first and second terminals, the first terminal of the sixth transistor coupled to the second terminal of the fifth transistor; and
a second capacitor having first and second terminals, the first terminal of the second capacitor coupled to the control terminal of the fourth transistor and the second terminal of the second capacitor coupled to the control terminal of the sixth transistor.

3. The apparatus of claim 2, wherein the level shifter circuit has a third input and a second output, the third input of the level shifter circuit coupled to the control terminal of the sixth transistor, and the second output of the level shifter circuit coupled to the control terminal of the fourth transistor.

4. The apparatus of claim 2, further comprising a seventh transistor having a control terminal and first and second terminals, the first terminal of the seventh transistor coupled to the second terminal of the fifth transistor, the second terminal of the seventh transistor coupled to the first terminal of the sixth transistor, and the control terminal of the seventh transistor coupled to a second voltage terminal.

5. The apparatus of claim 1, further comprising a fourth transistor having a control terminal and first and second terminals, the first terminal of the fourth transistor coupled to the second terminal of the second transistor, the second terminal of the fourth transistor coupled to the first terminal of the third transistor, and the control terminal of the fourth transistor coupled to a second voltage terminal.

6. The apparatus of claim 1, wherein the level shifter circuit comprises:
a fourth transistor having a control terminal and first and second terminals, the first terminal of the fourth transistor coupled to the first voltage terminal, and the control terminal of the fourth transistor coupled to a ground terminal;
a fifth transistor having a control terminal and first and second terminals, the first terminal of the fifth transistor coupled to the second terminal of the fourth transistor;
a sixth transistor having a control terminal and first and second terminals, the first terminal of the of the sixth transistor coupled to the second terminal of the fifth transistor, the second terminal of the sixth transistor coupled to the ground terminal, and the control terminal of the sixth transistor coupled to the control terminal of the third transistor;
a seventh transistor having a control terminal and first and second terminals, the first terminal of the seventh transistor coupled to the first voltage terminal, and the control terminal of the seventh transistor coupled to the second terminal of the fourth transistor;
an eighth transistor having a control terminal and first and second terminals, the first terminal of the eighth transistor coupled to the second terminal of the seventh transistor, and the second terminal of the eighth transistor coupled to the ground terminal;
a ninth transistor having a control terminal and first and second terminals, the first terminal of the ninth transistor coupled to the first voltage terminal, and the second terminal of the ninth transistor coupled to the second terminal of the seventh transistor;
a tenth transistor having a control terminal and first and second terminals, the first terminal of the tenth transistor coupled to the first voltage terminal, the second terminal of the tenth transistor coupled to the control terminal of the ninth transistor and to the control terminal of the fifth transistor, and the control terminal of the tenth transistor coupled to the second terminal of seventh transistor;
an eleventh transistor having a control terminal and first and second terminals, the first terminal of the eleventh transistor coupled to the second terminal of the tenth transistor, the second terminal of the eleventh transistor coupled to the ground terminal, and the control terminal of the eleventh transistor coupled to the second terminal of the seventh transistor;
a twelfth transistor having a control terminal and first and second terminals, the first terminal of the twelfth transistor coupled to the first voltage terminal, and the control terminal of the twelfth transistor coupled to the second terminal of the tenth transistor; and
a thirteenth transistor having a control terminal and first and second terminals, the first terminal of the thirteenth transistor coupled to the second terminal of the twelfth transistor, the second terminal of the thirteenth transistor coupled to the ground terminal, and the control terminal of the thirteenth transistor coupled to the second terminal of the tenth transistor.

7. The apparatus of claim 6, wherein the level shifter circuit comprises:
a first inverter circuit having input and outputs, the first input of the first inverter circuit coupled to the second terminal of the tenth transistor;
a first resistor having first and second terminals, the first terminal of the first resistor coupled to the output of the first inverter circuit, and the second terminal of the first resistor coupled to the control terminal of the first transistor;
a second inverter circuit having input and outputs, the first input of the second inverter circuit coupled to the second terminal of the twelfth transistor; and
a second resistor having first and second terminals, the first terminal of the second resistor coupled to the output of the second inverter circuit.

8. An apparatus, comprising:
a first level shifter circuit having first, second, third, and fourth inputs; and
a second level shifter circuit having first and second inputs, and first and second outputs, the first input of the second level shifter circuit coupled to the first input of the first level shifter circuit, the second input of the second level shifter circuit coupled to the second input of the first level shifter circuit, the first output of the second level shifter circuit coupled to the third input of the first level shifter circuit, and the second output of the second level shifter circuit coupled to the fourth input of the first level shifter circuit.

9. The apparatus of claim 8, wherein the first level shifter circuit comprises:
a first transistor having a control terminal and first and second terminals, the first terminal of the first transistor coupled to a first voltage terminal, in which the control terminal of the first transistor is coupled to the third input of the first level shifter circuit;
a voltage source having first and second terminals, the first terminal of the voltage source coupled to the first voltage terminal;
a second transistor having a control terminal and first and second terminals, the first terminal of the second transistor coupled to the second terminal of the first transistor, and the control terminal of the second transistor coupled to the second terminal of the voltage source;
a third transistor having a control terminal and first and second terminals, the first terminal of the third transistor coupled to the second terminal of the second transistor, in which the control terminal of the third transistor is coupled to the first input of the first level shifter circuit; and
a first capacitor having first and second terminals, the first terminal of the first capacitor coupled to the control terminal of the first transistor, the second terminal of the first capacitor coupled to the control terminal of the third transistor.

10. The apparatus of claim 9, wherein the first level shifter circuit further comprises:
a fourth transistor having a control terminal and first and second terminals, the first terminal of the fourth transistor coupled to the first voltage terminal, in which the control terminal of the fourth transistor is coupled to the fourth input of the first level shifter circuit;
a fifth transistor having a control terminal and first and second terminals, the first terminal of the fifth transistor coupled to the second terminal of the fourth transistor, and the control terminal of the fifth transistor coupled to the second terminal of the voltage source;
a sixth transistor having a control terminal and first and second terminals, the first terminal of the sixth transistor coupled to the second terminal of the fifth transistor, in which the control terminal of the sixth transistor is coupled to the second input of the first level shifter circuit; and
a second capacitor having first and second terminals, the first terminal of the second capacitor coupled to the control terminal of the fourth transistor and the second terminal of the second capacitor coupled to the control terminal of the sixth transistor.

11. The apparatus of claim 10, wherein the first level shifter circuit further comprises:
a seventh transistor having a control terminal and first and second terminals, the first terminal of the seventh transistor coupled to the second terminal of the second transistor, the second terminal of the seventh transistor coupled to the first terminal of the third transistor, and the control terminal of the seventh transistor coupled to a second voltage terminal; and
an eighth transistor having a control terminal and first and second terminals, the first terminal of the eighth transistor coupled to the second terminal of the fifth transistor, the second terminal of the eighth transistor coupled to the first terminal of the sixth transistor, and the control terminal of the eighth transistor coupled to the second voltage terminal.

12. The apparatus of claim 8, wherein the second level shifter circuit comprises:
a first transistor having a control terminal and first and second terminals, the first terminal of the first transistor coupled to a first voltage terminal, and the control terminal of the first transistor coupled to a ground terminal;
a second transistor having a control terminal and first and second terminals, the first terminal of the second transistor coupled to the second terminal of the first transistor;
a third transistor having a control terminal and first and second terminals, the first terminal of the of the third transistor coupled to the second terminal of the second transistor, the second terminal of the third transistor coupled to the ground terminal, and the control terminal of the third transistor coupled to the first input of the first level shifter circuit;
a fourth transistor having a control terminal and first and second terminals, the first terminal of the fourth transistor coupled to the first voltage terminal, and the control terminal of the fourth transistor coupled to the second terminal of the first transistor;
a fifth transistor having a control terminal and first and second terminals, the first terminal of the fifth transistor coupled to the second terminal of the fourth transistor, the second terminal of the fifth transistor coupled to the ground terminal, and the control terminal of the fifth transistor coupled to the second input of the first level shifter circuit;
a sixth transistor having a control terminal and first and second terminals, the first terminal of the sixth transistor coupled to the first voltage terminal, and the second terminal of the sixth transistor coupled to the second terminal of the fourth transistor;
a seventh transistor having a control terminal and first and second terminals, the first terminal of the seventh transistor coupled to the first voltage terminal, the second terminal of the seventh transistor coupled to the control terminal of the sixth transistor and to the control terminal of the second transistor, and the control terminal of the seventh transistor coupled to the second terminal of fourth transistor;
an eighth transistor having a control terminal and first and second terminals, the first terminal of the eighth transistor coupled to the second terminal of the seventh transistor, the second terminal of the eighth transistor coupled to the ground terminal, and the control terminal of the eighth transistor coupled to the second terminal of the fourth transistor;
a ninth transistor having a control terminal and first and second terminals, the first terminal of the ninth transistor coupled to the first voltage terminal, and the control terminal of the ninth transistor coupled to the second terminal of the seventh transistor; and
a tenth transistor having a control terminal and first and second terminals, the first terminal of the tenth transistor coupled to the second terminal of the ninth transistor, the second terminal of the tenth transistor coupled to the ground terminal, and the control terminal of the tenth transistor coupled to the second terminal of the seventh transistor.

13. The apparatus of claim 12, wherein the second level shifter circuit comprises:
a first inverter circuit having input and outputs, the first input of the first inverter circuit coupled to the second terminal of the seventh transistor;
a first resistor having first and second terminals, the first terminal of the first resistor coupled to the output of the first inverter circuit, and the second terminal of the first resistor coupled to the third input of the first level shifter circuit;
a second inverter circuit having input and outputs, the first input of the second inverter circuit coupled to the second terminal of the ninth transistor; and
a second resistor having first and second terminals, the first terminal of the second resistor coupled to the output of the second inverter circuit, and the second terminal of the second resistor coupled to the fourth input of the first level shifter circuit.

14. A system, comprising:
a first circuit having first and second outputs, the first circuit configured to operate in a first voltage domain;
a second circuit having an input, the second circuit configured to operate in a second voltage domain;
a level shifter circuit having first, second, third, and fourth inputs, and an output, the first input of the level shifter circuit coupled to the first output of the first circuit, the second input of the level shifter circuit coupled to the second output of the first circuit, and the output of the level shifter circuit coupled to the input of the second circuit, wherein the level shifter is configured to convert a signal received from the first circuit from the first voltage domain to the second voltage domain; and
a driver circuit having first and second inputs, and first and second outputs, the first input of the driver circuit coupled to the first input of the level shifter circuit, the second input of the driver circuit coupled to the second input of the level shifter circuit, the first output of the driver circuit coupled to the third input of the level shifter circuit, and the second output of the driver circuit coupled to the fourth input of the level shifter circuit, wherein the driver circuit is configured to drive the level shifter circuit in converting the signal from the first voltage domain to the second voltage domain.

15. The apparatus of claim 14, wherein the level shifter circuit comprises:
a first transistor having a control terminal and first and second terminals, the first terminal of the first transistor coupled to a first voltage terminal, in which the control terminal of the first transistor is coupled to the third input of the level shifter circuit;
a voltage source having first and second terminals, the first terminal of the voltage source coupled to the first voltage terminal;
a second transistor having a control terminal and first and second terminals, the first terminal of the second transistor coupled to the second terminal of the first transistor, and the control terminal of the second transistor coupled to the second terminal of the voltage source;
a third transistor having a control terminal and first and second terminals, the first terminal of the third transistor coupled to the second terminal of the second transistor, in which the control terminal of the third transistor is coupled to the first input of the level shifter circuit; and
a first capacitor having first and second terminals, the first terminal of the first capacitor coupled to the control terminal of the first transistor, the second terminal of the first capacitor coupled to the control terminal of the third transistor.

16. The apparatus of claim 15, wherein the level shifter circuit further comprises:
a fourth transistor having a control terminal and first and second terminals, the first terminal of the fourth transistor coupled to the first voltage terminal, in which the control terminal of the fourth transistor is coupled to the fourth input of the level shifter circuit;
a fifth transistor having a control terminal and first and second terminals, the first terminal of the fifth transistor coupled to the second terminal of the fourth transistor, and the control terminal of the fifth transistor coupled to the second terminal of the voltage source;
a sixth transistor having a control terminal and first and second terminals, the first terminal of the sixth transistor coupled to the second terminal of the fifth transistor, in which the control terminal of the sixth transistor is coupled to the second input of the level shifter circuit; and
a second capacitor having first and second terminals, the first terminal of the second capacitor coupled to the control terminal of the fourth transistor and the second terminal of the second capacitor coupled to the control terminal of the sixth transistor.

17. The apparatus of claim 16, wherein the level shifter circuit further comprises:
a seventh transistor having a control terminal and first and second terminals, the first terminal of the seventh transistor coupled to the second terminal of the second transistor, the second terminal of the seventh transistor coupled to the first terminal of the third transistor, and the control terminal of the seventh transistor coupled to a second voltage terminal; and
an eighth transistor having a control terminal and first and second terminals, the first terminal of the eighth transistor coupled to the second terminal of the fifth transistor, the second terminal of the eighth transistor coupled to the first terminal of the sixth transistor, and the control terminal of the eighth transistor coupled to the second voltage terminal.

18. The apparatus of claim 14, wherein the driver circuit comprises:
a first transistor having a control terminal and first and second terminals, the first terminal of the first transistor coupled to a first voltage terminal, and the control terminal of the first transistor coupled to a ground terminal;
a second transistor having a control terminal and first and second terminals, the first terminal of the second transistor coupled to the second terminal of the first transistor;
a third transistor having a control terminal and first and second terminals, the first terminal of the of the third transistor coupled to the second terminal of the second transistor, the second terminal of the third transistor coupled to the ground terminal, and the control terminal of the third transistor coupled to the first input of the level shifter circuit;
a fourth transistor having a control terminal and first and second terminals, the first terminal of the fourth transistor coupled to the first voltage terminal, and the control terminal of the fourth transistor coupled to the second terminal of the first transistor;
a fifth transistor having a control terminal and first and second terminals, the first terminal of the fifth transistor coupled to the second terminal of the fourth transistor, the second terminal of the fifth transistor coupled to the ground terminal, and the control terminal of the fifth transistor coupled to the second input of the level shifter circuit;
a sixth transistor having a control terminal and first and second terminals, the first terminal of the sixth transistor coupled to the first voltage terminal, and the second terminal of the sixth transistor coupled to the second terminal of the fourth transistor;
a seventh transistor having a control terminal and first and second terminals, the first terminal of the seventh transistor coupled to the first voltage terminal, the second terminal of the seventh transistor coupled to the control terminal of the sixth transistor and to the control terminal of the second transistor, and the control terminal of the seventh transistor coupled to the second terminal of fourth transistor;
an eighth transistor having a control terminal and first and second terminals, the first terminal of the eighth transistor coupled to the second terminal of the seventh transistor, the second terminal of the eighth transistor coupled to the ground terminal, and the control terminal of the eighth transistor coupled to the second terminal of the fourth transistor;
a ninth transistor having a control terminal and first and second terminals, the first terminal of the ninth transistor coupled to the first voltage terminal, and the control terminal of the ninth transistor coupled to the second terminal of the seventh transistor; and
a tenth transistor having a control terminal and first and second terminals, the first terminal of the tenth transistor coupled to the second terminal of the ninth transistor, the second terminal of the tenth transistor coupled to the ground terminal, and the control terminal of the tenth transistor coupled to the second terminal of the seventh transistor.

19. The apparatus of claim 18, wherein the driver circuit comprises:
a first inverter circuit having input and outputs, the first input of the first inverter circuit coupled to the second terminal of the seventh transistor;
a first resistor having first and second terminals, the first terminal of the first resistor coupled to the output of the first inverter circuit, and the second terminal of the first resistor coupled to the third input of the level shifter circuit;
a second inverter circuit having input and outputs, the first input of the second inverter circuit coupled to the second terminal of the ninth transistor; and
a second resistor having first and second terminals, the first terminal of the second resistor coupled to the output of the second inverter circuit, and the second terminal of the second resistor coupled to the fourth input of the level shifter circuit.

20. The system of claim 14, wherein the driver circuit comprises a direct current level shifter.
